(19) United States
(12) Patent Application Publication
(10) Pub. No.: US 2012/0231181 A1
(43) Pub. Date: Sep. 13, 2012

(54) INSULATION COVERAGE OF CVD ELECTRODE

(75) Inventors: Suhail Anwar, San Jose, CA (US); Robin L. Tiner, Santa Cruz, CA (US)

(73) Assignee: Applied Materials, Inc., Santa Clara, CA (US)

(21) Appl. No.: 13/405,488

(22) Filed: Feb. 27, 2012

Related U.S. Application Data
(60) Provisional application No. 61/450,889, filed on Mar. 9, 2011.

(51) Int. Cl. C23C 16/505; B32B 3/04; C23C 16/50

(52) U.S. Cl. 427/569; 118/723 R; 428/130

(57) ABSTRACT

Embodiments of the present invention relate to apparatus and methods for preventing arcing between a RF hot chamber components and grounded chamber body. One embodiment of the present invention provides an insulation cover for using in a plasma processing chamber. The insulation cover comprises a frame having an inner window for accommodating a gas distribution showerhead therein. The frame has an L-shaped cross section and configured to shield both a vertical portion and a horizontal portion of a chamber component from the gas distribution showerhead.

### CROSS-REFERENCE TO RELATED APPLICATIONS

This application claims benefit of U.S. Provisional Application Ser. No. 61/450,889 (Attorney Docket No. 15606L), filed Mar. 9, 2011, which is incorporated herein by reference.

### BACKGROUND

1. Field

Embodiments of the present invention relate apparatus and methods for preventing arcing between chamber components during plasma deposition. More particularly, embodiments of the present invention relate to an insulation cover used between a gas distribution showerhead and a chamber body to prevent arcing.

2. Description of the Related Art

Plasma enhanced chemical vapor deposition (PECVD) is generally employed to deposit thin films on substrates, such as semiconductor substrates, solar panel substrates, flat panel display (FPD) substrates, organic light emitting display (OLED) substrates, and other substrates. PECVD is a deposition method whereby processing gas is introduced into a processing chamber through a gas distribution showerhead disposed within a chamber body, such as the chamber lid. The showerhead spreads out the processing gas as it flows into a processing space between the showerhead and a susceptor supporting a substrate. The showerhead is electrically biased with an RF current to ignite the processing gas into a plasma. The chamber body/chamber lid is grounded. The susceptor, sitting opposite to the showerhead, is electrically grounded and functions as an anode. The plasma reacts to form a thin film of material on a surface of the substrate that is positioned on the susceptor.

Processing chambers for large area substrates require higher RF power compared to previous tools to achieve desired deposition rates. As the power increases, the tendency for arcing between the RF hot diffuser and grounded lid also naturally increases. Arcing has become the main factor limiting use of higher power processes. Insulation material can be inserted between the diffuser and the lid, however arcing still occurs.

Therefore, improved insulations for showerheads are needed for PECVD chambers.

### SUMMARY

Embodiments of the present invention relate to apparatus and methods for preventing arcing between a RF hot chamber components and grounded chamber body.

One embodiment of the present invention provides an insulation cover for use in a plasma processing chamber. The insulation cover comprises a frame having an inner window for accommodating a gas distribution showerhead therein. The frame has an L-shaped cross section and configured to shield both a vertical surface and a horizontal surface of an adjacent chamber component from the gas distribution showerhead.

Another embodiment of the present invention provides an insulation cover for using in a plasma processing chamber. The insulation cover includes a plurality of corners. Each corner comprises a horizontal portion, and two vertical portions, the horizontal portion is elongated and forms a corner angle, the vertical portions extend vertically from an edge of the horizontal portion so that the vertical portions and the horizontal portion form a L-shaped cross section, and a gap is present between the two vertical portions. The insulation cover further comprises a plurality of corner reinforcers stacked over the plurality of corners. Each corner reinforcers comprises a vertical portion and two horizontal portions, the vertical portion bends to form the corner angle, and two horizontal portions extend horizontally from a lower edge of the vertical portion, and the vertical portion of the corner reinforcer is operable to mate with a respective corner and covers the gap between the vertical portions of the corner. The insulation cover further includes a plurality of side bars having L-shaped cross sections and assembleable to extend between the corner reinforcers and corners.

Another embodiment of the present invention provides a plasma processing chamber. The plasma processing chamber comprises a chamber component having an inwardly extending shelf, and a gas distribution showerhead disposed inward of the shelf. The gas distribution showerhead is connected to a RF power source for generating a plasma between the gas distribution showerhead and a substrate disposed in the plasma processing chamber, and the chamber component is part of a return path of the RF power source. The plasma processing chamber further comprises one or more insulation layers disposed between the chamber component and the gas distribution showerhead to provide electrical insulation therebetween, and an insulation cover attached to the chamber component. The insulation cover blocking horizontal gaps present between the chamber component and the gas distribution showerhead.

Yet another embodiment of the present invention provides a method for plasma processing. The method comprises shielding a chamber component to block a horizontal line of sight gap present the insulators disposed between the chamber component and a gas distribution showerhead. The gas distribution showerhead is coupled to a RF power source, and the chamber component is part of a return path of the RF power source. The method further comprises providing a processing gas to the plasma processing chamber through the gas distribution showerhead, and generating a plasma of the processing gas between the gas distribution showerhead and a substrate positioned in the plasma processing chamber, wherein the RF current of the plasma returns to the RF power source via the chamber component.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of a plasma chamber according to one embodiment of the present invention.

FIG. 2 is a schematic perspective view of an insulation cover according to one embodiment of the present invention.

FIG. 3 is an exploded view of a corner of the rectangular insulation cover according to one embodiment of the present invention.

FIGS. 4A-4G schematically illustrate formation of components of an insulation cover according to one embodiment of the present invention.

FIG. 5A is a schematic sectional view of a plasma chamber having an insulation cover according to one embodiment of the present invention.

FIG. 5B is a schematic sectional view of a corner of a plasma chamber having an insulation cover according to one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally relate to an apparatus and method for preventing arcing between an RF hot chamber component and adjacent chamber components residing on or at the same potential as an RF return path to the RF power source coupled to the RF hot chamber component. Embodiments of the present invention provides an insulation cover disposed between an RF hot chamber component and a grounded chamber component at the same potential as the chamber component residing on an RF return path. The insulation cover blocks horizontal line of sight gaps that may be present between the RF hot gas distribution showerhead, or other RF hot chamber components and grounded chamber components to reduce arcing in RF processing chambers. In one embodiment, an insulation cover is disposed around inner edges of the chamber lid to prevent arcing between the gas distribution showerhead and the chamber lid. The insulation cover may include one or more pieces.

The embodiments discussed herein will make reference to a large area PECVD chamber manufactured and sold by AKT America, a subsidiary of Applied Materials, Inc., Santa Clara, Calif. It is to be understood that the embodiments discussed herein may be practiced in other plasma processing chambers as well, including chambers sold by other manufacturers.

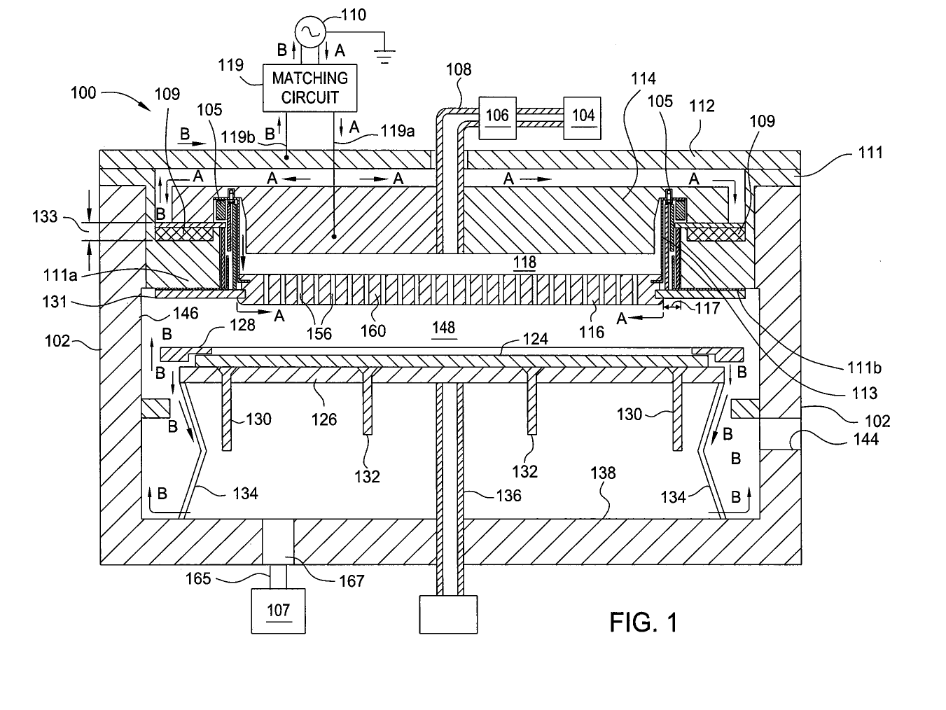

FIG. 1 is a schematic sectional view of a plasma chamber 100 according to one embodiment of the present invention. In the embodiment, the plasma chamber 100 is a PECVD apparatus.

The plasma chamber 100 includes a chamber body 102 that encircle the interior of the plasma chamber 100. The chamber body 102 may be formed by a metal, for example aluminum or stainless steel. The chamber body 102 provides the vacuum enclosure for the side, bottom, and a portion of the top, of the chamber interior. In one embodiment, the chamber body 102 includes a bottom 138, sidewalls 146 and a lid 111.

A susceptor 126 having a stem 136 is disposed within a plasma chamber 100. In one embodiment, the susceptor 126 may have a flat upper surface that supports a substrate 124. Lift pins 130, 132 hang through the susceptor 126 for lifting the substrate 124 for loading and unloading.

During loading, the substrate 124 is inserted into the plasma chamber 100 through a slit valve opening 144 formed through the sidewalls 146 of the chamber body 102. The plasma chamber 100 may include one or more straps 134 coupled between the susceptor 126 and the chamber body 102. The one or more straps 134 are configured to provide shortened RF return path (discussed further below) by connecting the susceptor 126 to the chamber body 102 while by passing the stem 126.

The plasma chamber 100 may include a shadow frame 128 movably disposed over the susceptor 126 to cover a peripheral region of the susceptor 126. In one embodiment, the shadow frame 128 is formed by an electrically insulating material and electrically shields the RF current that travels along the susceptor 126 from the RF current that travels along the inside of the sidewalls 146 of the chamber body 102.

A backing plate 114 is coupled to the lid 111. The backing plate 114 in turn is coupled to a gas distribution showerhead 116. One or more layers of insulating material 105 are disposed between the chamber lid 111 and the backing plate 114 to electrically isolate RF hot and grounded chamber components. In one embodiment, the backing plate 114 rests on an inwardly extending shelf 111a of the chamber lid 111.

A cover 112 is coupled to the top of the chamber lid 111 to protect technicians from direct contact with chamber components that are RF hot during processing.

The chamber body 102, and gas distribution showerhead 116 encloses a processing region 148 between the gas distribution showerhead 116 and the substrate 124 disposed on the susceptor 126.

The gas distribution showerhead 116 may be hung under the backing plate 114 by one or more brackets 113. A plenum 118 is formed between the backing plate 114 and the gas distribution showerhead 116. The plenum 118 is in fluid communication with a gas source 104 via a tube 108. Processing gas provided by the gas source 104 flows from the plenum 118 into the processing region 148 through a plurality of gas passages 156 formed through the gas distribution showerhead 116.

A remote plasma source 106 may be coupled to the tube 108 to provide active species for chamber cleaning. During processing, for example during a deposition process, the processing gas is fed from the gas source 104, through the remote plasma source 106 and through a tube 108 while the processing gas is not ignited into a plasma in the remote plasma source 106. During chamber cleaning, the cleaning gas is sent from the gas source 104 into the remote plasma source 106 where it is ignited into a plasma before entering the chamber. In one embodiment, the tube 108 may be formed from an electrically conductive material.

A vacuum pump 107 maintains a desired level of pressure within the plasma chamber 100. Processing gases and reaction products from the processing region 148 are removed from the processing region 148 through an exhaust port 167, and then through an exhaust channel 165 to the vacuum pump 107.

The chamber body 102, the cover 112, the backing plate 114, the bracket 113, and the gas distribution showerhead 116 are formed from electrically conductive material and form a path for the RF current used in igniting a plasma within the plasma chamber 100. Suitable conductive material may be aluminum, or stainless steel.

A RF power source 110 is connected to the gas distribution showerhead 116 or the backing plate 114 through an RF matching circuit 119. The RF matching circuit 119 may include a first output 119a which is RF hot and a second output 119b which is RF grounded. The gas distribution showerhead 116 or the backing plate 114 is connected to the first output 119a. As such, the backing plate 114 and the gas distribution showerhead 116 are RF hot chamber components. The chamber body 102 and cover 112 are electrically connected to the second output 110b thereby defining a RF return path back to the RF power source 110 through the RF matching circuit 119. The susceptor 126 is electrically connected to the chamber body 102 through the straps 134.

During operation, the RF current from the RF matching circuit 119 travels along arrow A from the backing plate 114 to the front face 160 of the gas distribution showerhead 116. The RF current ignites the processing gas into a plasma in the processing region 148 between the gas distribution showerhead 116 and the substrate 124 disposed on the susceptor 126, which is an RF grounded chamber component for being electrically connected to the chamber body 102 coupled to the RF grounded second output 119a. The RF current flows from the gas distribution showerhead 116 to the susceptor 126 igniting a plasma in the processing region 148. The RF current then flows from the susceptor 126 to the stripes 134, then along the inner walls of the chamber body 102, chamber lid 111 and chamber cover 112 along arrow B. The RF current then flows back to the second output 119a of the RF matching circuit 119, and eventually returns to the RF power source 110 and completes the circuit with the power source 110.

A high potential difference may exist between the RF delivery current travelling along the surface of the gas distribution showerhead 116 and the RF returning current traveling along the chamber lid 111. Because of the potential difference, arcing may occur between the gas distribution showerhead 116 and the chamber lid 111. Embodiments of the present invention provide an insulation cover disposed over chamber components near the RF hot gas distribution showerhead to prevent arcing.

In the embodiment shown in FIG. 1, the gas distribution showerhead 116 is surrounded by the chamber lid 111 while the chamber lid 111 is at RF ground potential and the gas distribution showerhead 116 is RF hot during processing. A clearance space 117 is defined between the gas distribution showerhead 116 and the chamber lid 111 to allow for differential thermal expansion and to space chamber components having different electrical potentials. The layers of insulating material 105 are disposed in the clearance space 117 between the chamber lid 111 and the gas distribution showerhead 116 for electrical insulation. In one embodiment, a ceramic liner 131 is disposed under the chamber lid 111 so that the layers of insulating material 105 can rest thereon. A clearance space 133 is defined between the backing plate 114 and the chamber lid 111. Layers of insulating material 109 are disposed within the clearance space 133 between the chamber lid 111 and the backing plate 114. The layers of thermal insulating materials 105, 109 may include thin strips of insulation materials combined together to fill irregular spaces.

The layers of insulating material 105 function to keep concentration of the electric field inside the dielectric material to prevent arcing. The layers of insulating material 105 also prevent line of sight between the chamber lid 111 and the gas distribution showerhead 116. However, gaps may exist within the layers of thermal insulating material 105 to allow thermal expansion or because of the structural characteristics of the insulating material 105.

An insulation cover assembly 115 is disposed over an inner corner 111b of the chamber lid 111. The insulation cover assembly 115 wraps around regions of the chamber lid 111 that face the gas distribution showerhead 116 and other RF hot chamber component to prevent arcing within the processing region 148. The insulation cover assembly 115 is positioned to block the line of sight between the gas distribution showerhead 116 and the chamber lid 111. The insulation cover assembly 115 prevents arcing between the gas distribution showerhead 116 and the chamber lid 111 even if there are processing gases present in the gaps of the layers of insulating material 105.

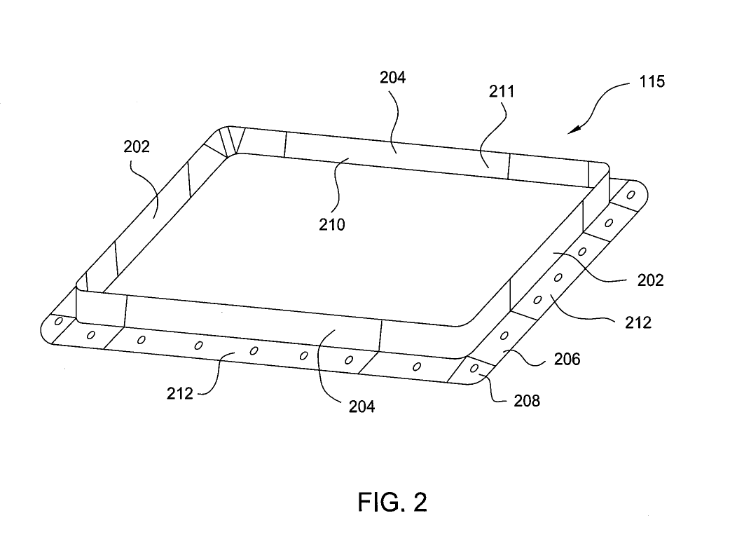

In one embodiment, the insulation cover assembly 115 has an L shape cross section and provides coverage to both horizontal and vertical inner walls of the chamber lid 111. FIG. 2 is a schematic perspective view of the insulation cover assembly 115 according to one embodiment of the present invention. The insulation cover assembly 115 is generally a frame having an inner window 210 large enough to accommodate the gas distribution showerhead 116. The insulation cover assembly 115 may have a vertical wall 211 framing the inner window 210. The vertical wall 211 is configured to cover vertical walls of the chamber lid 111 or other portions of the chamber body 102 facing the gas distribution showerhead 116. A horizontal wall 212 extends outwards from a lower end of the vertical wall 211 so that the insulation cover assembly 115 has an L-shaped sectional view. In one embodiment, the vertical wall 211 and the horizontal wall 212 are continuous without any gap to provide continuous coverage around the chamber lid 111.

In one embodiment, the insulation cover assembly 115 has a rectangular inner window 210 configured to provide insulation between rectangular chamber bodies and rectangular gas distribution showerheads. However, the insulation cover assembly 115 may have other shapes, such as circular, for various chamber designs.

The insulation cover assembly 115 is formed from electrically insulative, dielectric materials. In one embodiment, the insulation cover assembly 115 is formed from a polymer, for example polytetrafluoroethylene (PTFE, or TEFLON®). In one embodiment, the insulation cover assembly 115 may be formed from one or more polytetrafluoroethylene sheets. In one embodiment, the insulation cover assembly 115 may be formed from one or more polymer sheets having a thickness of about 0.04 inch.

In one embodiment, the insulation cover assembly 115 includes two or more pieces of L-shaped components overlapping with one another to form a frame. Multi-piece configurations provide tolerance to the insulation cover assembly 115 against thermal expansion. Multi-piece configurations also provide convenience for manufacturing.

In one embodiment, the insulation cover assembly 115 includes four side bars 202, 204, four corners 208, and four corner reinforcers 206 overlapping with one another. In one embodiment, the side bars 202 may be shorter than the side bars 204 giving the insulation cover assembly 115 a rectangular shape.

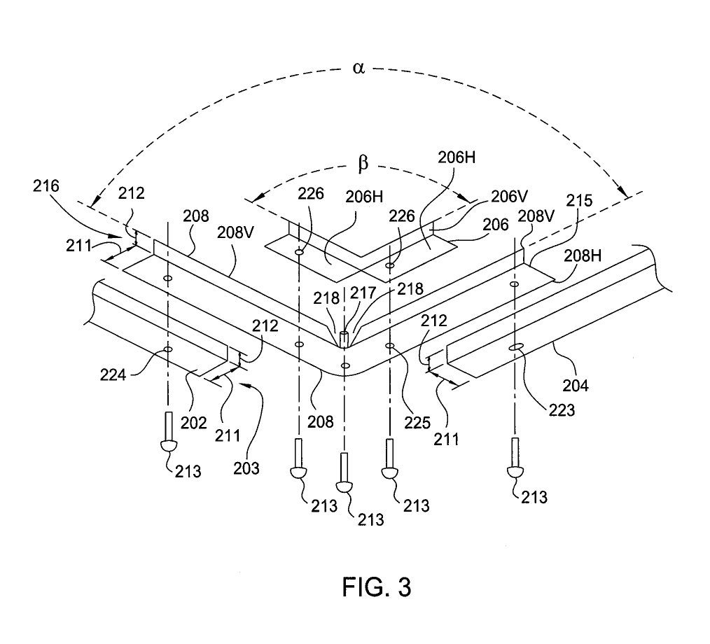

FIG. 3 is an exploded view of a corner of the rectangular insulation cover assembly 115 relative to the chamber lid 111 and the gas distribution showerhead 116. The side bars 204 may have an L-shaped cross-section formed from insulative materials. In one embodiment, the side bars 202, 204 may be formed from strips of insulative sheets, such as from strips of polytetrafluoroethylene sheet. Each side bar 202 or 204 is substantially linear and configured to cover a substantial portion of one side of the chamber lid 111. The L-shape of each side bar 202 or 204 provides coverage to both a vertical surface 111V and a horizontal surface 111H of the chamber lid 111 from the RF-hot gas distribution showerhead 116. In one embodiment, each side bar 202, 204 may have a width 211a of about 3.35 inch for covering the horizontal surface 111H and a width 212a of about 0.8 inch for covering the vertical surface 111V.

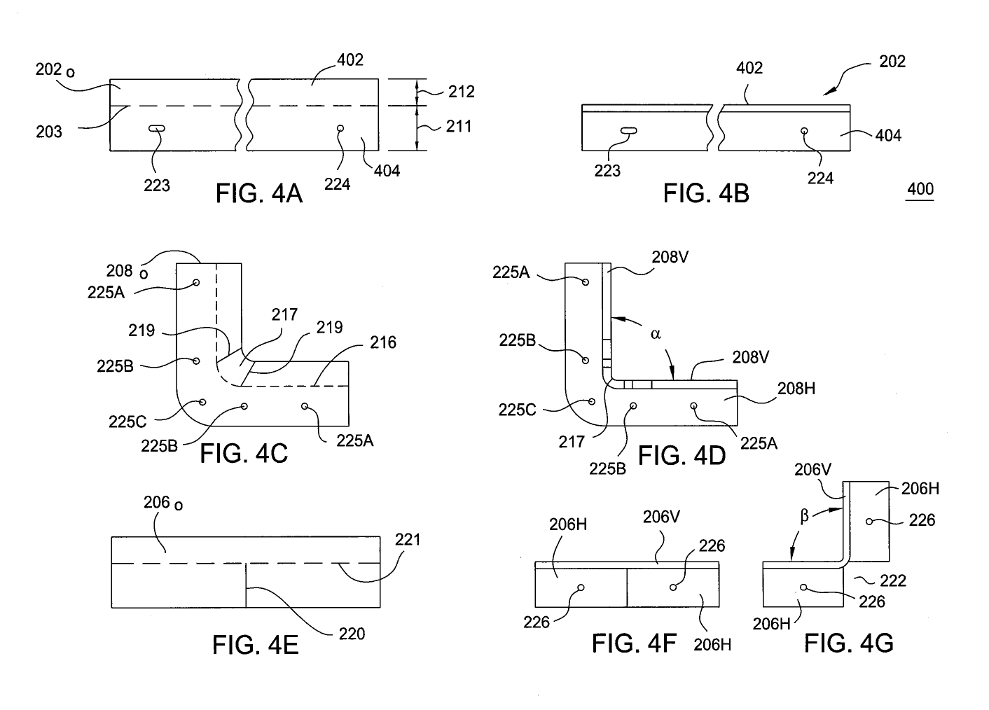

FIGS. 4A-4B schematically illustrates one embodiment to form the side bars 202, 204. Each side bar 202, 204 may start from an elongated flat sheet 202o made of insulating material as shown in FIG. 4A. The elongated flat sheet 202o has a first portion 402 and a second portion 404 bent along line 203 to form the L-shaped section as shown in FIG. 4B. One or more mounting holes 223, 224 may be formed on the second portion 404 of the side bar 202, 204. The mounting holes 223, 224 are used for attaching the side bar 202, 204 to the chamber lid 111 by screws 213. In one embodiment, the mounting hole is an elongated in shape to allow thermal expansion.

Referring to back to FIG. 3, the corner 208 has a horizontal portion 208H and vertical portion 208V forming a L-shaped cross section. The corner 208 forms an angle α of approximately 90 degrees. The horizontal portion 208H is configured to match the horizontal surface 111H of the chamber lid 111 at the corner region 111e. The horizontal portion 208H is a continuous surface without any gaps. Each corner 208 has two vertical portions 208V and a tab 217 vertically extending from the horizontal portion 208H. The tab 217 elects from the horizontal portion 208H at the vertices of the angle α. The tab 217 is disposed between the vertical portions 208V. Gaps 218 are defined between the tab 219 and each vertical portion 208V. The tab 217 extends generally perpendicular to the horizontal portion 208H. One or more mounting holes 225A, 225B, 225C may be formed through the horizontal portion 208H to allow the corner 208 attached to the chamber lid 111 by one or more screws.

When assembled, the corner 208 overlaps with both the long side bar 204 and the short side bar 202 so that no portion of the chamber lid 111 is exposed. The screws 213 extend through the mounting holes 223, 224 and 225A to secure the corner 208 and side bars 202, 204.

The corner reinforcer 206 also has an L-shaped cross section and forms an angle β of approximately 90 degrees. The corner reinforcer 206 has a continuous vertical portion 206V configured to dispose over the corner 208 to cover the gaps 218 on the corner 208. The corner reinforce 206 has two horizontal portions 206H extending orthogonal to each other from the vertical portion 206V.

FIGS. 4C-4D schematically illustrate a method for formation of the corner 208 according to one embodiment of the present invention. Each corner 208 may start from an angular flat sheet 208o made of insulating material as shown in FIG. 4C. Two cuts 219 are made at the tip of the angle. The angular flat sheet 208o is then bent approximately 90 degrees along line 216 to form the L-shaped cross section with the tab 217, as shown in FIG. 4D.

FIGS. 4E-4G schematically illustrate a method for formation of the corner reinforcer 206 according to one embodiment of the present invention. Each corner reinforcer 206 may start from an elongated flat sheet 206o made of insulating material as shown in FIG. 4E. A partial cut 220 is made near a center of the elongated flat sheet 206o. The elongated flat sheet 206o is then bent approximately 90 degrees along line 221 to form the L-shaped cross section having vertical and horizontal portions 20 as shown in FIG. 4F. The partial cut 220 allows the vertical portion 206V to be bent approximately 90 degrees to form the angle β, thereby separating the two horizontal portions 206H with a gap 222. The corner reinforce 206 has an angled and continuous vertical portion 206V. Two mounting holes 226 are formed through the horizontal portions 206H. The mounting holes 226 align with the mounting holes 225B of the corner 208 to allow coupling of the corner 208 and corner reinforce 206 by screws 213, as shown in FIG. 3.

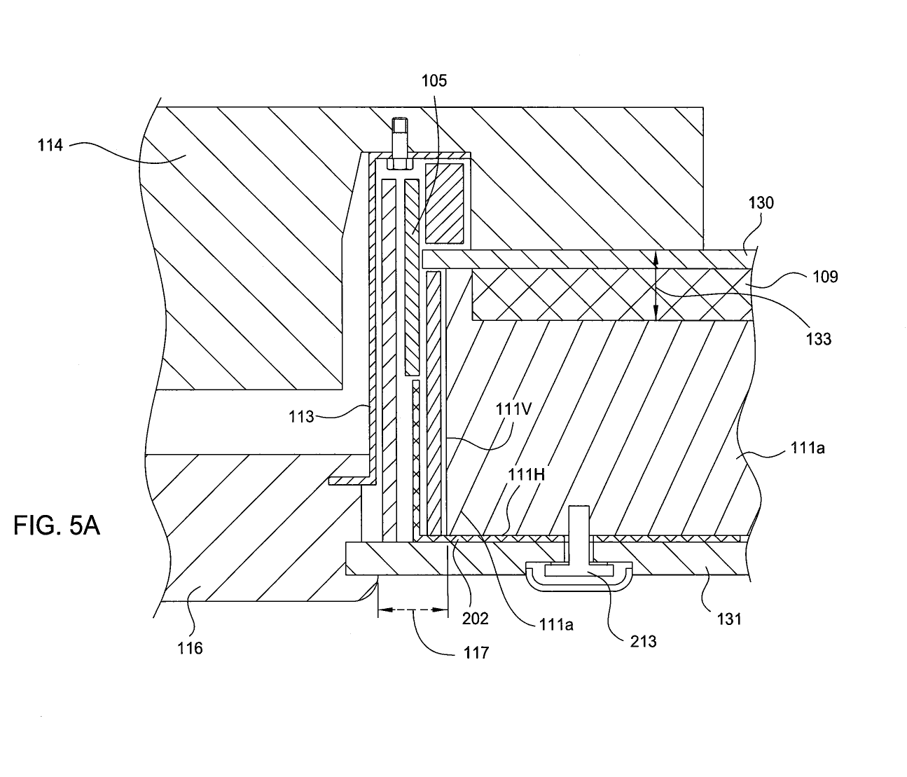

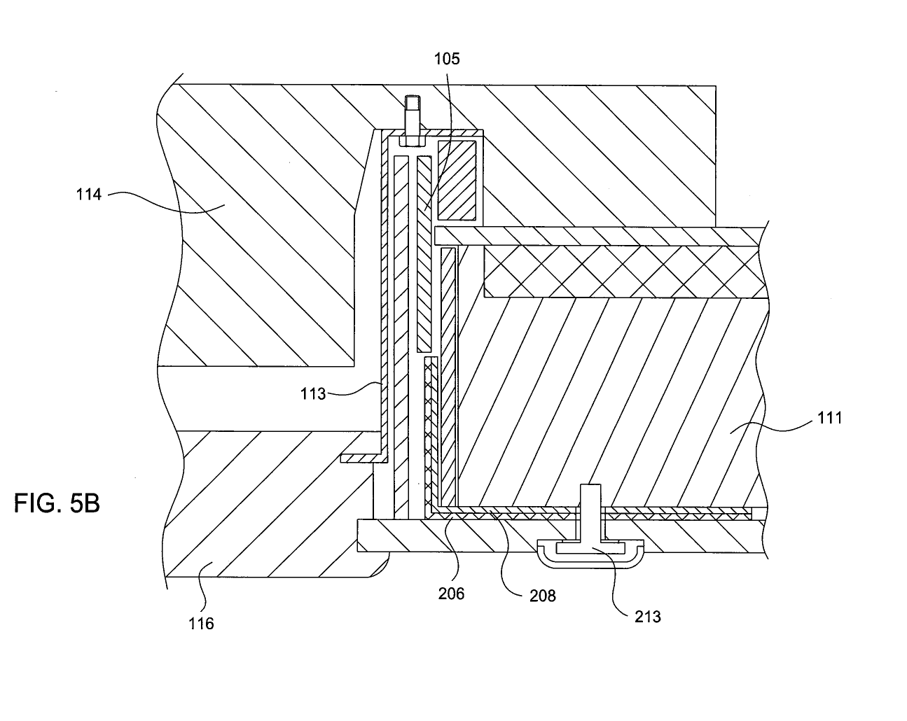

FIG. 5A is a partial sectional view of the plasma chamber 100 having the insulation cover assembly 115 at one side of the plasma chamber 100. The gas distribution showerhead 116 is coupled to the backing plate 114 by bracket 113. The backing plate 114 rests on the inwardly extending shelf 111a of the chamber lid 111. Clearance space 117 is designed between the chamber lid 111 and the gas distribution showerhead 116 and the bracket 113. The clearance space 117 are filled with insulating materials 105 so that the chamber lid 111 is electrically insulated from the RF hot components, such as the gas distribution showerhead 116. The insulation cover assembly 115 (side bar 202 is shown in FIG. 5A) covers both the vertical surface 111V and horizontal surface 111H of the chamber lid 111 blocking the line of sight between the gas distribution showerhead 116 and the chamber lid 111. The presence of the insulation cover assembly 115 prevents arcing between the gas distribution showerhead 116 and the chamber lid 111 even when processing gas escapes into gaps within the insulating material 105. In one embodiment, ceramic liners 131 may be disposed over the insulation cover assembly 115 and secured by the same screws 213 securing the cover 215.

FIG. 5B is a schematic sectional view of a corner of the plasma chamber 100 having then insulation cover assembly 115. At corners, the insulation cover 115 include the corner 208 and the corner reinforcer 206 overlapping one other to provide complete coverage near the corner area.

Even though the insulation cover described above includes multiple pieces. Embodiments of the present invention contemplate to cover an insulation cover of other configurations, for example an insulation cover fabricated as a single one-piece component.

While the foregoing is directed to embodiments of the present invention, other and further embodiments of the invention may be devised without departing from the basic scope thereof, and the scope thereof is determined by the claims that follow.

What is claimed is:

1. An insulation cover for using in a plasma processing chamber, comprising:
a plurality of corners, wherein each corner comprises a horizontal portion, and two vertical portions, the horizontal portion is elongated and forms a corner angle, the vertical portions extend vertically from an edge of the horizontal portion so that the vertical portions and the horizontal portion form a L-shaped cross section, and a gap is present between the two vertical portions;
a plurality of corner reinforcers stacked over the plurality of corners, wherein each corner reinforcers comprises a vertical portion and two horizontal portions, the vertical portion bends to form the corner angle, and two horizontal portions extend horizontally from a lower edge of the vertical portion, and the vertical portion of the corner reinforcer is operable to mate with a respective corner and covers the gap between the vertical portions of the corner; and
a plurality of side bars having L-shaped cross sections and assembleable to extend between the corner reinforcers and corners.

2. The insulation cover of claim 1, wherein the side bars, the corner reinforcers and the corners are fabricated from a dielectric material.

3. The insulation cover of claim 2, wherein the dielectric material is polytetrafluoroethylene.

4. The insulation cover of claim 1, wherein each of the plurality of corners comprises a tab positioned in the gap between the two vertical positions, and the tab extends vertically from the horizontal portion.

5. The insulation cover of claim 1, wherein the plurality of corners comprise four corners with the corner angle of about 90 degrees.

6. The insulation cover of claim 1, wherein the corner reinforcers and the corners have aligned mounting holes formed in the horizontal sections.

7. The insulation cover of claim 1, wherein the corners and the side bars have aligned mounting holes in the horizontal sections.

8. The insulation cover of claim 7, therein at least one of the mounting holes is elongated.

9. A plasma processing chamber, comprising:
a chamber component;
a gas distribution showerhead disposed horizontally inward of the chamber component;
one or more insulation layers disposed between the chamber component and the gas distribution showerhead to provide electrical insulation therebetween; and
an insulation cover attached to the chamber component, wherein the insulation cover blocks horizontal line of sight gaps between the chamber component and the gas distribution showerhead.

10. The plasma processing chamber of claim 9, wherein the insulation cover comprises a frame having an inner window for accommodating a gas distribution showerhead therein, the frame has an L-shaped cross section and configured to shield both a vertical surface and a horizontal surface of a chamber component from the gas distribution showerhead.

11. The plasma processing chamber of claim 10, wherein the frame comprises two or more structures having an L-shaped cross section.

12. The plasma processing chamber of claim 11, wherein the frame comprises:
four side bars each having an L shaped cross section; and
four corner assemblies each having an L-shaped cross section, wherein the four side bars and the four corner assemblies form a rectangular frame, and the side bars overlaps with the corner assemblies.

13. The plasma processing chamber of claim 12, wherein each corner assembly comprises:
a first component having an L-shaped cross section, wherein the first component has an angled horizontal portion without gap, and an angled vertical portion with gaps; and
a second component having an L-shaped cross section, wherein the second component has an angled vertical portion without gap, and the first and second components overlap with one another.

14. The plasma processing chamber of claim 11, wherein the frame is formed from strips of polytetrafluoroethylene sheet.

15. The plasma processing chamber of claim 9, wherein the chamber component is a chamber lid.

16. The plasma processing chamber of claim 15, further comprising:
a backing plate supported the inwardly extending shelf of the chamber lid, wherein the gas distribution showerhead is attached to the backing plate.

17. A method for plasma processing, comprising:
shielding a chamber component to block a horizontal line of sight gaps between insulators disposed between the chamber component and a gas distribution showerhead, wherein the gas distribution showerhead is coupled to a RF power source, and the chamber component is part of a return path of the RF power source;
providing a processing gas to the plasma processing chamber through the gas distribution showerhead; and
generating a plasma of the processing gas between the gas distribution showerhead and a substrate positioned in the plasma processing chamber, wherein the RF current of the plasma returns to the RF power source via the chamber component.

18. The method of claim 17, wherein shielding the chamber component comprises using an insulation cover having an L-shaped cross section to cover the chamber components.

19. The method of claim 18, wherein insulation cover comprises multiple insulation components having L-shaped cross section.

20. The method of claim 18, wherein the insulation cover comprises one or more strips of insulation sheets.
